(19) United States
(12) Patent Application Publication
(10) Pub. No.: US 2013/0319328 A1
(43) Pub. Date: Dec. 5, 2013

(54) APPARATUS FOR PREPARING, IN PARTICULAR COATING, SAMPLES

(71) Applicant: Leica Mikrosysteme GmbH, Vienna (AT)

(72) Inventors: Paul WURZINGER, Deutsch Wagram (AT); Anton LANG, Vienna (AT)

(21) Appl. No.: 13/906,444

(22) Filed: May 31, 2013

(30) Foreign Application Priority Data
Jun. 4, 2012 (AT) A50220/2012

(51) Int. Cl. H01J 37/26

(52) U.S. Cl. CPC H01J 37/261
USPC 118/696

(57) ABSTRACT

An apparatus (100, 200) for coating specimens comprises a vacuum chamber (105, 205); at least one source, associated with the vacuum chamber, of a coating material; at least one sample holder (120) for positioning at least one sample within the vacuum chamber; an electronic control system; an operating console (103, 203) for inputting instructions for the electronic control system; and a housing (101, 201) surrounding at least the vacuum chamber and the electronic control system. The housing has a width (b, b″) that substantially corresponds to the width (b′) of the vacuum chamber. The vacuum chamber comprises a door (106, 206) on a front side of the chamber. The operating console is located in or in front of a base region (102, 202) of the housing. The at least one source is installable on an upper side of the vacuum chamber.

### CROSS REFERENCE TO RELATED APPLICATIONS

This application claims priority of Austrian patent application number A50220/2012 filed Jun. 4, 2012, the entire disclosure of which is incorporated by reference herein.

### FIELD OF THE INVENTION

The invention relates to an apparatus for coating specimens, for example for subsequent electron microscopy investigation, comprising a vacuum chamber in the form of a metallic vessel; at least one source, associated with the vacuum chamber, of a coating material; at least one sample holder configured to position at least one sample to be prepared within the vacuum chamber in a sample position; an electronic control system; an operating console for inputting instructions for the electronic control system; and a housing that surrounds at least the vacuum chamber and the electronic control system.

### BACKGROUND OF THE INVENTION

Preparation apparatuses of the kind recited are known in a wide variety of embodiments and are used to coat samples and substrates under a high-vacuum and fine-vacuum atmosphere, inter alia to coat electron microscopy specimens with thin conductive material layers. In cathode sputtering (also known as “sputter coating”), high-energy ions, usually an activated noble gas plasma or a noble gas ion beam, displaces metal atoms out of a target (such as platinum or gold); they then become deposited onto the sample and form a layer thereon. Also sufficiently known are vacuum evaporation apparatuses with which evaporation material is evaporated by thermal heating with electric current. The known methods of carbon thread evaporation, carbon rod evaporation, metal evaporation out of a sagger or from a coil, and evaporation by electron beam are widely used in electron microscopy, in particular in the manufacture of impression films and reinforcing films for transmission electron microscopy, and very thin conductive surface layers for scanning electronic microscopy samples. Also used are numerous devices that permit a combination of multiple different sample preparation techniques. For cryo-scanning electron microscopy (cryo-SEM) or transmission electron microscopy (TEM), samples are prepared (among other techniques) in freeze fracture units and freeze etching units under high vacuum, the processing tools respectively necessary for freeze fracturing or freeze etching also being arranged, in addition to the components provided for coating, in the vacuum chambers of these units.

Known devices for the preparation of electron microscopy samples are manufactured, for example, by the Cressington, Quorum Technologies, Denton Vacuum, and Gatan companies. In their most common embodiment, the known devices are made up substantially of a removable glass cylinder in which the sample is arranged on a sample holder, e.g. in the form of a sample stage; a cover for the glass cylinder which contains the source of the coating material; and a base having the electronic control system, the vacuum pumps, and the receptacle for the glass cylinder. In some devices the vacuum chamber is a metal vessel. Larger units also comprise a front door.

The known units have the following disadvantages:
The units are usually very wide and occupy a large footprint in the laboratory. Laboratory space (which is usually limited) therefore cannot be efficiently utilized.
The removable glass cylinder can easily be damaged at the sealing surfaces by chipping, causing problems in terms of vacuum tightness.
The cover including the source of the coating material, which is usually mounted tiltably, is often problematic in terms of vacuum tightness.
In order to remove the samples, it is required to move the coating source incorporated in the cover when the cover is opened. Residues of an incompletely evaporated material (e.g. carbon thread), or coating particles detaching from the vicinity of the source, can fall onto the sample.
Because of the risk of implosion, a shatter shield around the glass cylinder is necessary for safety.
In order to connect vacuum transfer devices for samples (for example, for cryo-fixed samples to be prepared for subsequent investigation using cryo-electron microscopy), it is necessary to replace the glass cylinder by a metal cylinder having lateral flanges. Leaving aside the cumbersome handling, this necessitates even more laboratory space.
Ergonomic operation for users is difficult, in particular in the case of units having a glass cylinder (operation from above).

EP 1 531 189 A1 describes a vapor deposition device that is accessible from the inside of a clean room. The document U.S. Pat. No. 4,311,725 relates to a device for thin-film deposition whose vacuum chamber is bell-shaped; a housing surrounding the chamber is not mentioned. JP 2009-132966 A describes a system for depositing films in which the side walls of the vacuum chamber are removable.

### SUMMARY OF THE INVENTION

An object of the invention is therefore to eliminate the disadvantages recited above and to make available an apparatus which has the advantages of a small footprint in the lab, ergonomic operation, and an improved modular design, such as for use as a desktop device. A further object is to solve problems occurring with the known apparatuses in terms of vacuum sealing and sample contamination.

The stated object is achieved by an apparatus for coating specimens, for example for subsequent electron microscopy investigation, of the kind recited earlier, in that according to the present invention the housing has a width that substantially corresponds to the width of the vacuum chamber, the vacuum chamber comprising a door present on a front side of the chamber, the operating console being located in or in front of a base region of the housing arranged below the vacuum chamber, and the at least one source is mounted or configured to be mounted on the upper side of the vacuum chamber.

This approach enables to achieve the stated object particularly efficiently. The narrow width of the apparatus, defined substantially by the width of the vacuum chamber, allows maximum utilization of laboratory surface space. Since the vacuum chamber is made of metal, e.g. stainless steel or aluminum, and has a door located on the front side, in the event of an implosion the glass shards end up in the chamber, with the result that the apparatus is not critical in terms of safety as compared with the known apparatuses recited above having a glass cylinder. The apparatus according to the present invention furthermore has significant advantages for an operator, since the placement of the door on the front side provides ergonomically favorable access to the samples; in particular, the samples can be removed without first having to move the sources. The arrangement of the operating console in or in front of a base region of the housing arranged below the vacuum chamber is also ergonomically favorable.

The term “front side” is to be understood as that side of the unit (of the apparatus) which faces toward the user. The term “longitudinal direction” is that horizontal direction which extends perpendicular to the front side. “Depth” is the maximum extension dimension along the longitudinal direction. The term “width” refers to the maximum extension dimension in a horizontal direction perpendicular to the longitudinal direction (i.e., parallel to the front side).

According to the present invention, the housing has a width that corresponds substantially to the width of the vacuum chamber. The term “substantially” means that the housing of the apparatus is at a distance from the outer rim of the metallic vacuum chamber (metal vessel) no greater than the necessary installation spacing (taking into account production tolerances). The external width of the metal vessel is increased with respect to the interior by an amount equal to the necessary wall thicknesses and to the space for the installation of holding means and closure means for the front door and any sensors.

The person skilled in the art has available a plurality of coating material sources and corresponding methods for applying a material coating. In one aspect, the source can be an evaporation source having a thread- or rod-shaped evaporation material that is received in the evaporation source and, as described earlier, is evaporated by heating with electric current. The thread- or rod-shaped evaporation material is, for example, a carbon thread or carbon rod. The source can furthermore be designed for the known method of cathodic sputtering (also referred to as “sputter coating”) in which, as described above, high-energy ions, typically a noble gas plasma or a noble gas ion beam, are used to displace metal atoms (gold, platinum, etc.) out of a target; they then become deposited onto the sample and form a layer thereon. The source can furthermore be set up for electron beam evaporation of a coating material. In one aspect, the apparatus can be equipped with a corona discharge device for surface treatment and cleaning of the sample surfaces to be coated.

The apparatus can encompass one or more sources. The apparatus typically encompasses up to two of the sources recited above. Thanks to the narrow width of the apparatus according to the present invention, multiple apparatuses can be arranged next to one another in space-saving fashion if a demand exists for further coating methods.

The at least one sample is received in a sample holder. A sufficiently known variety of sample holders are available to one skilled in the art from the generally available existing art. The at least one sample holder can be implemented, for example, as a sample stage, a large variety being likewise available to one skilled in the art with regard to the configuration of the sample stage, for example tiltable and rotatable sample stages, pin sample stages, or planetary rotary stages. To enable the greatest possible modularity, the sample stage can be replaceable.

It is advantageous if the walls of the vessel are protected from coating using removable panels or other shielding apparatuses. These panels can easily be cleaned in the deinstalled state. Laborious cleaning of the vessel is thus no longer necessary. In addition, various sets of protective panels can be used for different coating methods. This minimizes the influence on one coating operation by others, for example by secondary sputtering from the walls.

In one aspect, the apparatus can be used for preparing samples in a fine vacuum (up to 10⁻³ mbar), and in another aspect for preparing samples in a high vacuum (up to 10⁻⁷ mbar, in special cases up to 10⁻⁸ mbar).

The term “sample” refers to specimens for scientific experiments or investigations, for example for investigation in an electron microscope. For these investigations the samples are in most cases located on an electron microscopy sample carrier, the term “sample carrier” referring to all carriers suitable for electron microscopy and for electron microscopy sample preparation. Examples thereof are the grids used principally in a TEM but also in an SEM and sufficiently known, which comprise variously shaped holes (honeycomb, slots, etc.) or a grid of a defined mesh size. In SEM, silicon wafers, graphite discs, and conductive double-sided adhesive tabs can also, for example, be used.

According to one aspect of the invention, the front side of the vacuum chamber is a flat surface having an opening constituted therein, and the door is constituted by a plate, held externally at the edge of the opening, with which the opening is sealable in vacuum-tight fashion. This makes possible particularly good sealing, and sealing problems are avoided. In a subsidiary aspect, the vacuum chamber has a cuboidal basic shape, one side of the cube forming the front side.

The door preferably has a viewing window so that processes occurring in the vacuum chamber can be monitored.

For the preparation of electron microscopy samples and for subsequent transfer of the sample from the apparatus into an electron microscope, it is useful if the apparatus is designed for the preparation of samples for subsequent investigation in an electron microscope, and if at least one sample is receivable on the sample holder in a sample receptacle reversibly fastenable on the sample holder. This enable detachment of the sample receptacle, including the at least one sample received thereon, from the sample stage and transferring it into the electron microscope for subsequent electron-microscope investigation. For this purpose the electron microscope comprises a corresponding holder for the sample receptacle.

For replacement and/or cleaning of the sources, it is useful if each of the at least one sources is received in a removable feedthrough and can be fastened thereto on the upper side of the vacuum chamber.

For reasons of safety, it is favorable if a protective hood is arranged above the at least one source and comprises a switch element that activates upon opening of the protective hood and is connected to an interruptor for the power supply of the at least one source. The protective hood is advantageously implemented as an access cover, arranged over the exchangeable source, that is equipped with a safety switch. Once the protective hood is opened, the sources can easily and safely be removed for replacement and/or cleaning.

In order to make possible a particularly narrow width and thus optimum utilization of laboratory footprint, it is favorable if the housing abuts laterally against the vacuum chamber at the latter's maximum lateral extension; it may be advantageous if it exhibits no more than the tolerance spacing necessary for reliable installation.

The operating console is preferably implemented as a touchscreen of known type. In one aspect, the electronic control system is arranged below and/or behind the vacuum chamber. Preferably, however, the electronic control system is arranged below the vacuum chamber, since this may result in an elevated vacuum chamber, offering improved ergonomics for the operator.

For many applications and preparation methods it is desirable to connect attachments to the vacuum chamber. In a further aspect, therefore, the apparatus comprises flanges located laterally on the vacuum chamber, onto which attachments fed through the housing, in particular a transfer device, a transfer lock, or a cooling device having a reservoir for a cryogen, can be attached. Because of the narrow width and, associated therewith, the slender configuration of the apparatus, it is therefore possible to connect attachments via lateral flanges on the left or right without taking up an excessive amount of laboratory footprint. Cryofixed samples, for example, which are cooled very quickly in order to avoid the formation of ice crystals, must be transferred in the cooled state into the apparatus according to the invention for further sample preparation. This transfer of the cryofixed sample is very critical, since upon contact with moist air the sample immediately becomes covered with ice crystals. The transfer therefore preferably occurs with the aid of a special (vacuum) transfer device, for example with a Leica EM VCT 100 vacuum cryotransfer device. In addition, uncooled sample holders having samples received therein can be transferred into the vacuum chamber of the apparatus through a transfer lock. In a subsidiary aspect, a cooling device, for example a container having liquid nitrogen, may furthermore be attached in order to cool the samples present in the vacuum chamber via cooling belts, and/or in order to improve the vacuum as a result of the cold surfaces of the container, which function similarly to a cryopump.

In a particularly space-saving variant, the vacuum chamber comprises connectors for vacuum supply, which connectors are arranged exclusively on the back side of the vacuum chamber.

In a refinement of the invention, provision is made that a device for sample cryopreparation, in particular freeze fracturing, freeze etching, freeze drying, and impression techniques, is arranged inside the vacuum chamber. This refinement makes possible sample preparation utilizing sample cryopreparation, in combination with one or more coating techniques (e.g. metal coating and/or carbon coating) under a high vacuum of 10⁻⁷ mbar, in a single device. The processing tools that are necessary for cryopreparation and are sufficiently known, for example a cold knife, are correspondingly arranged in the vacuum chamber. The door located on the front side of the vacuum chamber, which usefully comprises a viewing window, allows an ergonomic posture for the operator during manipulation of the sample.

For many electron microscopy applications it is very important that the material layer deposited onto the sample have a specific thickness that must not exceed or fall below a certain tolerance range. It is advantageous for this reason if a quartz oscillator for measuring the deposited coating material layer thickness is arranged in the vacuum chamber. Quartz oscillators of this kind are sufficiently known to one skilled in the relevant art, and are typically arranged in the immediate vicinity of the sample.

### BRIEF DESCRIPTION OF THE DRAWING VIEWS

The invention, together with further details and advantages, will be explained in further detail below with reference to two exemplifying embodiments, namely an apparatus for sample preparation in fine vacuum and an apparatus for sample preparation in high vacuum, which are shown in the attached individual drawings in which, in schematic form:

FIG. 1 is a perspective view, from the top left, of a first embodiment of an apparatus according to the present invention for sample preparation in fine vacuum,

FIG. 2 is a perspective view, from the top right, of the apparatus of FIG. 1,

FIG. 3 is a side view of the apparatus of FIG. 1,

FIG. 4 is a rear view of the apparatus of FIG. 1,

FIG. 5 is a perspective view of the vacuum chamber of the apparatus of FIG. 1 with the door open and without the housing, electronic control system, and operating console,

FIG. 6 is a front view of the vacuum chamber as shown in FIG. 5,

FIG. 7 is a perspective view of the rear region of the vacuum chamber as shown in FIG. 5,

FIG. 8 is a perspective view, from the top left, of a further embodiment of an apparatus according to the present invention for sample preparation in high vacuum,

FIG. 9 is a perspective view, from the top right, of the apparatus of FIG. 8,

FIG. 10 is a side view of the apparatus of FIG. 8, and

FIG. 11 is a rear view of the apparatus of FIG. 8.

### DETAILED DESCRIPTION OF THE INVENTION

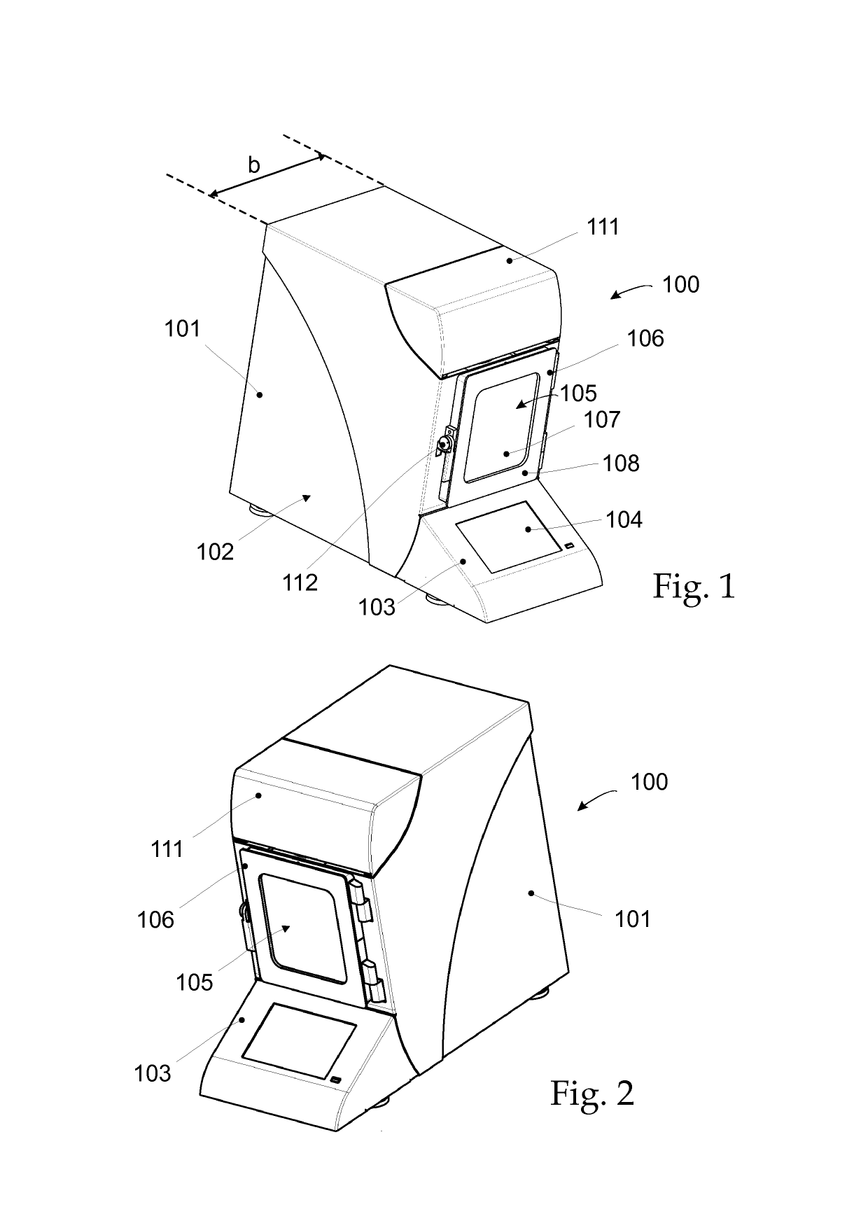

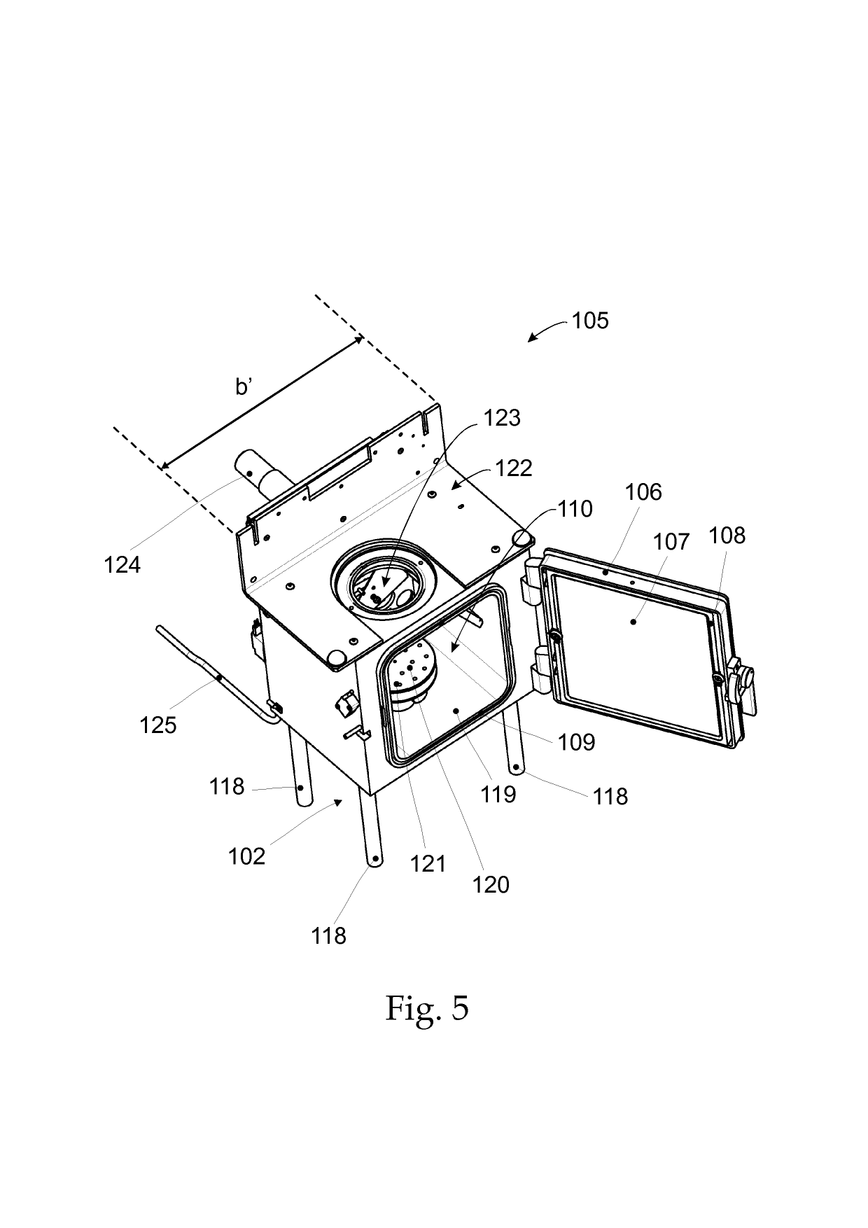

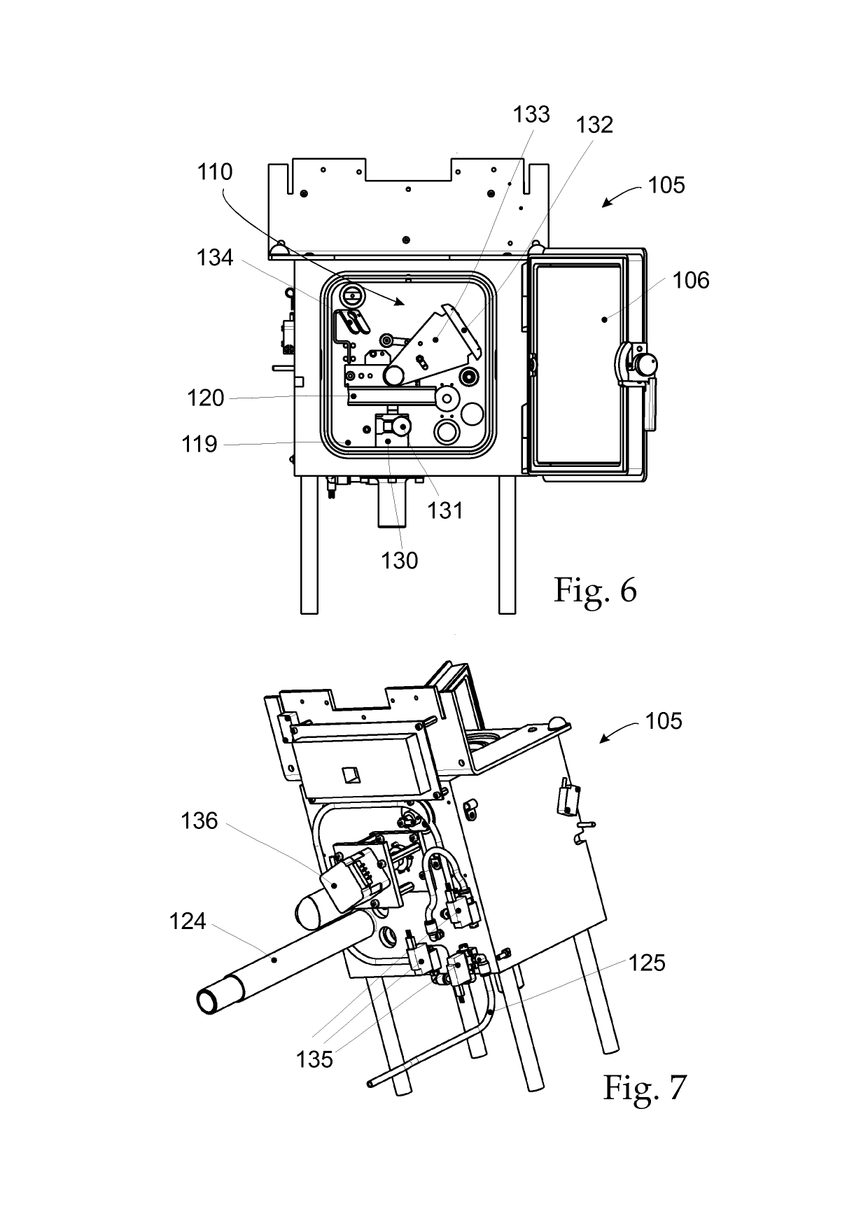

FIG. 1 is a perspective view, from the top left, of an apparatus 100 that is provided for sample preparation in a fine vacuum, i.e. a vacuum of up to 10⁻³ mbar. FIG. 2 is a perspective view, from the top right, of apparatus 100. A vacuum chamber 105 made of metal, and an electronic control system that is not visible in FIG. 1, are arranged inside a housing 101. The electronic control system is located in a base region 102 below and in a region behind vacuum chamber 105. Base region 102 is also the region that is located below the lower edge of vacuum chamber 105. Located in front of base region 102 of housing 101 is an operating console 103 having a touchscreen 104. The sample is located inside vacuum chamber 105 on a sample stage 120 (see FIGS. 5 and 6). Vacuum chamber 105 has on its front side a door 106 into which is recessed a viewing window 107, constituted from a glass plate, for visual monitoring of the preparation operation taking place in vacuum chamber 105. A frame 108 surrounding viewing window 107 guides viewing window 107 to a seal or gasket 109 (see FIGS. 5 and 6). Vacuum chamber 105 is closed off in vacuum-tight fashion by closing door 106 with a closure 112. Housing 101 has a width b that substantially corresponds to the width b′ of vacuum chamber 105 accommodated therein. The term “substantially” means that housing 101 is at a distance from the outer rim of the metallic vacuum chamber 105 no greater than the necessary installation spacing (taking into account production tolerances). The external width b′ of the vacuum chamber 105 may be augmented with respect to interior 110 (see FIG. 5) of vacuum chamber 105 by an amount equal to the necessary wall thicknesses and to the space for the installation of holding means and closure means (e.g. closure 112) for door 106 and any sensors. The at least one source of a coating material, e.g. an evaporation source for e.g. a carbon thread, or a sputter source having a sputter target made, for example, of gold, platinum and the like, is arranged on the upper side of vacuum chamber 105. Access to vacuum chamber 105 in order to replace and/or clean the sources is created by means of an access cover 111 of housing 101; as described in more detail below in FIGS. 5 and 6, vacuum chamber 105 itself has on its upper side a removable feedthrough for receiving the at least one source.

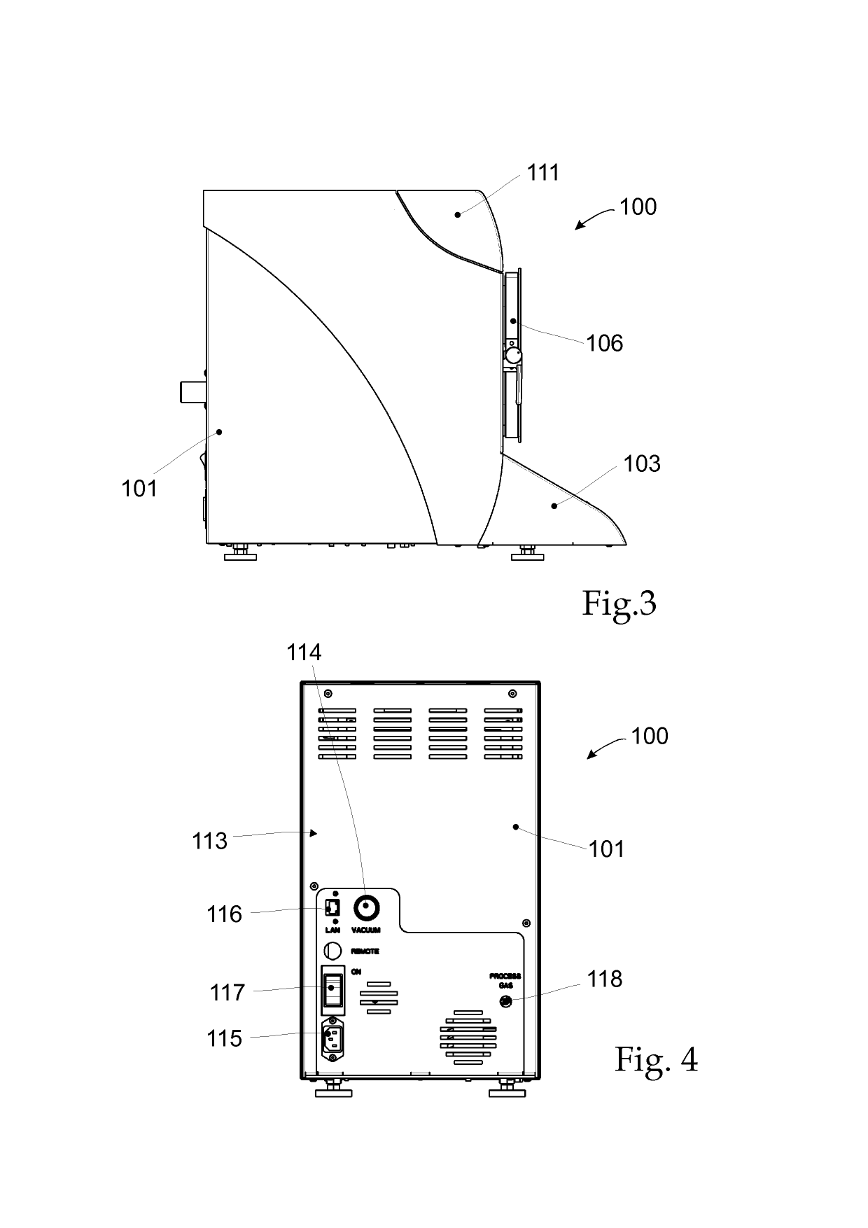

FIG. 3 is a side view of apparatus 100. FIG. 4 is furthermore a rear view of apparatus 100, showing back region 113 of housing 101. Located in back region 113 are the necessary equipment connectors as well as, in particular, a vacuum connector 114, a power connector 115, and a LAN connector 116, as well as on/off switch 117 and a passthrough 118 for a feed hose for a process gas (e.g. noble gas such as argon, oxygen, and the like).

FIG. 5 is a perspective view of vacuum chamber 105 of the apparatus of FIG. 1 with its door 106 open, providing a view into interior 110; in order to make vacuum chamber 105 visible, housing 101, the electronic control system, and operating console 103 have been removed. Frame 108 surrounding viewing window 107 guides viewing window 107 to seal 109. As already mentioned above, the electronic control system is accommodated behind and below the metallic vacuum chamber 105, inter alia in the unoccupied base region 102 constituted by support feet 118. Located inside vacuum chamber 105 is a sample stage 120 fastened releasably in bottom region 119 of vacuum chamber 105. The sample stage is vertically adjustable and replaceable, and can be removed from vacuum chamber 105 for easier securing of the samples. Several sample receptacles 121 for receiving the samples are located on sample stage 120, the samples in turn usually being mounted on a suitable sample carrier as described earlier in the descriptive introduction. The vacuum chamber has a width b; as already described above, housing 101 has a width b that substantially corresponds to width b′ of vacuum chamber 105. The at least one source of a coating material, for example at least one evaporation source for e.g. a carbon thread and/or at least one sputter source having a sputter target made e.g. of gold, platinum, and the like, is arranged on the inner upper side of vacuum chamber 105. The sources are each received in a feedthrough that is connected releasably in vacuum-tight fashion to the vacuum chamber. Vacuum chamber 105 correspondingly comprises on its upper side, in its ceiling region 122, an opening 123 that can be closed off in vacuum-tight fashion by means of the feedthrough. Thanks to the removable feedthrough for the sources, the latter can easily be replaced or removed for cleaning For safety reasons, there is arranged above the feedthrough a protective hood 111 (FIGS. 1 to 3) which comprises a switch element that activates upon opening of protective hood 111 and is connected to an interruptor for the power supply of the source, for example in the form of a safety switch. After protective hood 111 is opened, the sources can easily and safely be removed for replacement and/or cleaning Also visible in FIG. 5 are a vacuum connector tube 124 for connecting vacuum chamber 105 to a vacuum pump located outside apparatus 100, and feed hose 125 for a process gas.

FIG. 6 is a front view of vacuum 105 as depicted in FIG. 5, with a direct view into interior 110 of the open vacuum chamber 105. Receiving mechanism 130 for sample stage 120, which mechanism is connected to the underside of chamber 119, is depicted here. In the embodiment depicted, the stage is vertically adjustable manually and can be secured with a knurled screw 131. Vertical adjustment can in the same way also occur in motorized fashion, however, e.g. via a spindle drive, in which case the motor and linkage mechanism and the corresponding vacuum feedthroughs replace the simple receptacle 130. FIG. 6 furthermore shows a shutter 132 that can be pivoted in between the source and sample in order to protect the sample from any contamination in the context of source cleaning and ignition operations. In the embodiment shown, shutter 132 is slid aside in motorized fashion with an arm 133, and is positioned between the source and the samples using a spring (not depicted) as arm 133 rotates back. Also visible at the top left in the chamber is a receptacle 134 for a layer thickness measurement head (not depicted), for example a quartz sensor. Individual edges of this receptacle 134 at the same time mark specific predefined distances to the source, so that the distance between samples received on sample stage 120 and the coating source can easily be adjusted.

FIG. 7 is a perspective view of the back-side region of vacuum chamber 105 as depicted in FIG. 5, in which, as mentioned, the connectors for vacuum, power supply, and process gas are located. Also located here are valves 135 for controlling the process gas and for venting chamber 105. As described above, shutter 132 is actuated via an arm 133 that is moved by motor 136. Because all these connectors and control elements extend to the rear, out of the back-side region, the width b′ of vacuum chamber 105, and consequently also the width b of apparatus 100, is kept very narrow.

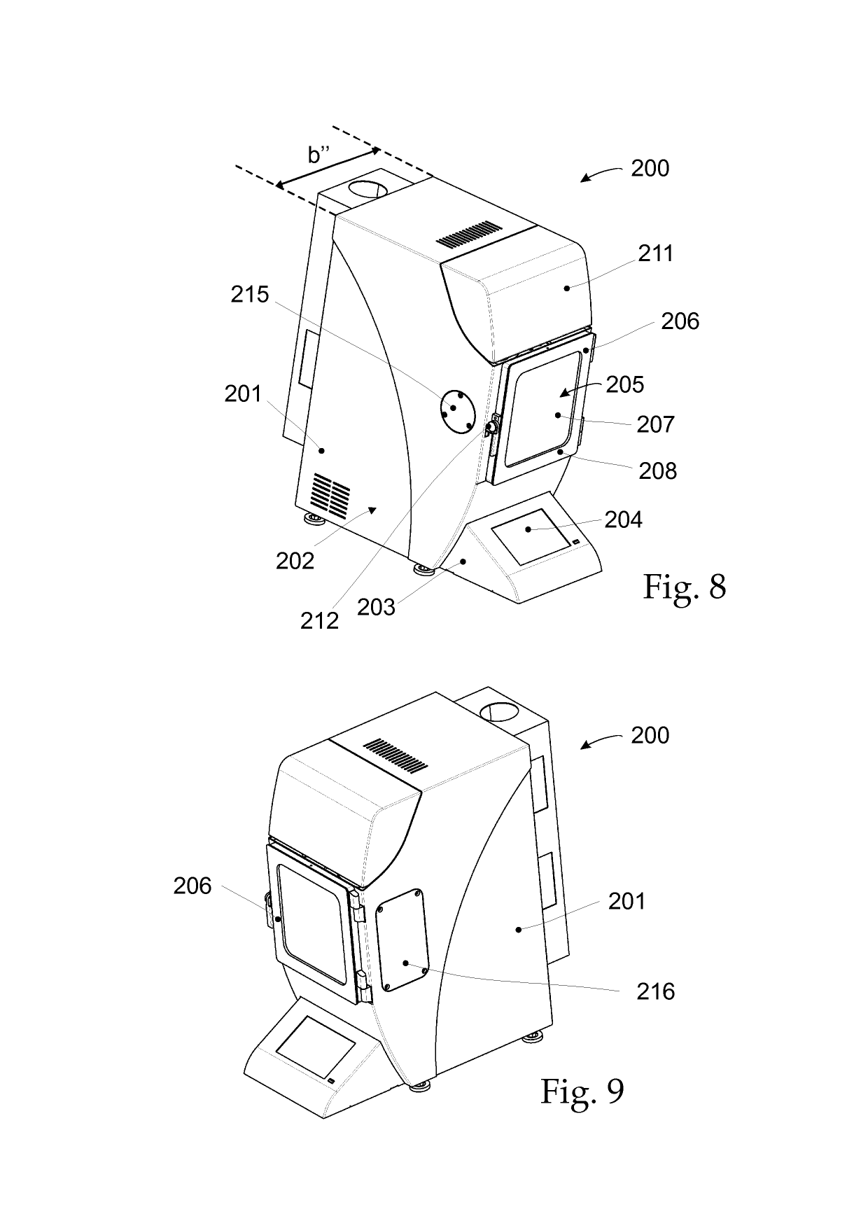

FIG. 8 is a perspective view, from the top left, of a further embodiment of an apparatus 200 for sample preparation in high vacuum, i.e. in a vacuum of better than 10⁻³ mbar to 10⁻⁷ mbar, possibly 10⁻⁸ mbar. FIG. 9 is a perspective view, from the top right, of apparatus 200. Analogously to the apparatus shown in FIGS. 1 to 7 for sample preparation in a fine vacuum, with apparatus 200 a vacuum chamber 205 made of metal and an electronic control system (not visible) are arranged inside a housing 201. The electronic control system, as well as the necessary pumps, e.g. a turbomolecular pump and a preceding membrane pump, are located below and behind vacuum chamber 205, preferably in a base region 202 of housing 201. Located in front of base region 202 of the housing is an operating console 203 having a touchscreen 204. The sample is located inside vacuum chamber 205 and, similarly to apparatus 100, is arranged of a sample stage. Vacuum chamber 205 has on its front side a door 206 into which is recessed a viewing window 207, constituted from a glass plate, for visual monitoring of the preparation operation taking place in vacuum chamber 205. A frame 208 surrounding viewing window 207 guides viewing window 207 to a seal. Vacuum chamber 205 is closed off in vacuum-tight fashion by closing the door with a closure 212. Analogously to apparatus 100, housing 201 of apparatus 200 also has a width b″ that substantially corresponds to the width of vacuum chamber 205 accommodated therein. The at least one source of a coating material, e.g. an evaporation source for e.g. a carbon thread, or a sputter source having a sputter target made, for example, of gold, platinum and the like, is arranged on the upper side of vacuum chamber 205. Access to vacuum chamber 205 in order to replace and/or clean the sources is created by means of an access cover 211 of housing 201; analogously to vacuum chamber 105 described above, vacuum chamber 205 itself comprises a respective removable feedthrough below access cover 211 for each source that is arranged. Analogously to cover 111, access cover 211 also performs the function of a protective hood. Also arranged laterally on vacuum chamber 205 are flanges that, in the illustrations, are closed of by blind flanges 215 (FIGS. 8) and 216 (FIG. 9). Attachments fed through housing 201, in particular a transfer device, a transfer lock, or a cooling device having a reservoir for a cryogen, can be attached to these flanges. Because of the narrow width and, associated therewith, the narrow configuration of apparatus 200, it is therefore possible to connect attachments via lateral flanges on the left or right without thereby taking up an excessive amount of laboratory footprint. For example, cryofixed samples that are cooled very quickly in order to avoid the formation of ice crystals are transferred in the cooled state into the apparatus according to the invention for further sample preparation (e.g. freeze fracturing, freeze etching, freeze drying, etc.). This transfer of the cryofixed sample is very critical, since upon contact with moist air the sample immediately becomes covered with ice crystals. The transfer is therefore accomplished with the aid of a special vacuum transfer device, for example with a Leica EM VCT 100 vacuum cryotransfer device. The processing tools and devices necessary for cryopreparation (e.g. freeze fracturing, freeze etching) are correspondingly proved for these purposes in vacuum chamber 205. Uncooled sample holders having samples received therein can furthermore be transferred through a transfer lock into the vacuum chamber of the apparatus. A cooling device, for example a Dewar vessel filled with liquid nitrogen, can furthermore be attached in order to cool the samples present in the vacuum chamber via cooling belts, and/or in order to improve the vacuum as a result of the cold surfaces of the container, which function similarly to a cryopump.

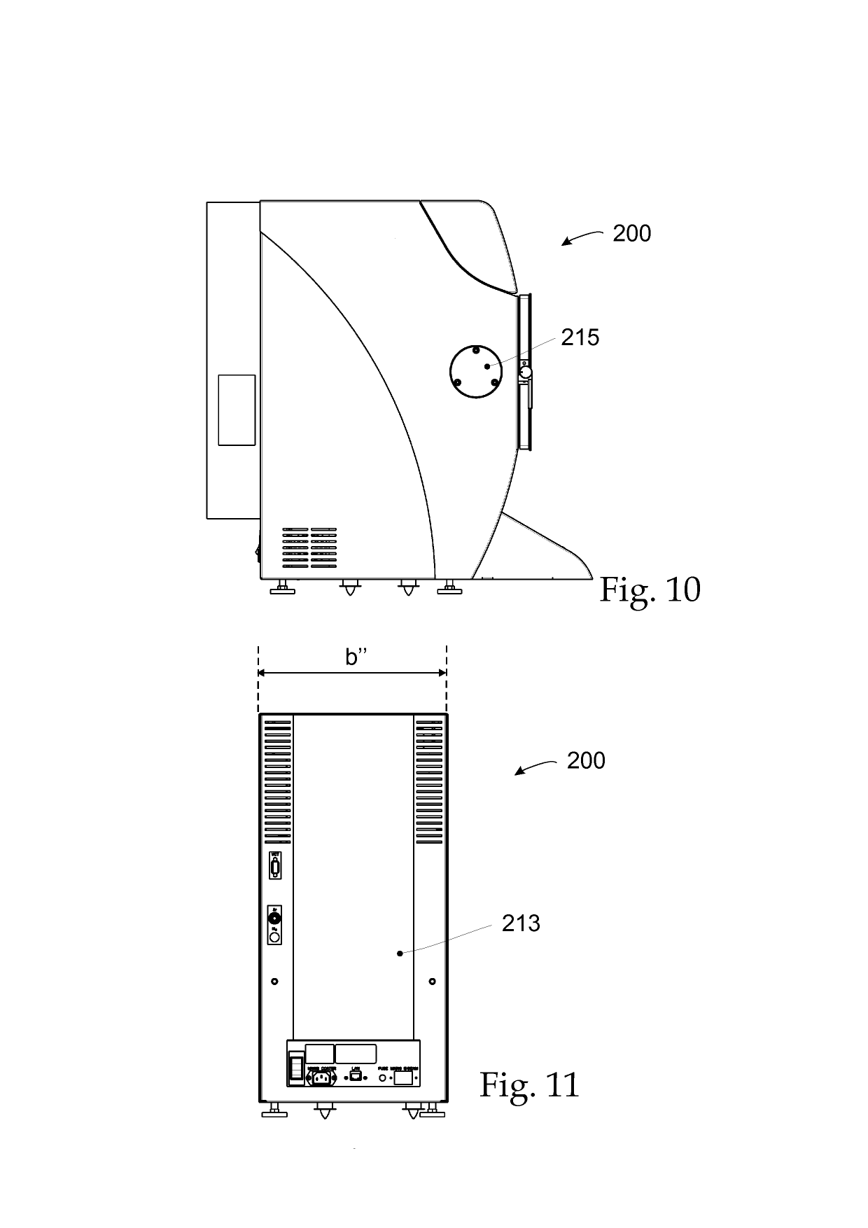

FIG. 10 is a side view of apparatus 200. FIG. 11 further presents a rear view of apparatus 200 showing back region 213 of housing 201 and of apparatus 200. The necessary equipment connectors, such as process gas, power, and LAN connectors, are located exclusively in back region 213, with the result that the width b″ of apparatus 200 can be kept very narrow.

What is claimed is:

1. An apparatus (100, 200) for coating specimens, comprising:
a vacuum chamber (105, 205) in the form of a metallic vessel;
at least one source, associated with the vacuum chamber (105, 205), of a coating material;
at least one sample holder (120) configured to position at least one sample to be prepared within the vacuum chamber (105, 205) in a sample position;
an electronic control system;
an operating console (103, 203) for inputting instructions for the electronic control system; and
a housing (101, 201) that surrounds at least the vacuum chamber (105, 205) and the electronic control system;
wherein the housing (101, 201) has a width (b, b″) that substantially corresponds to the width (b′) of the vacuum chamber (105, 205);
the vacuum chamber (105, 205) comprising a door (106, 206) present on a front side of the chamber,
the operating console (103, 203) being located in or in front of a base region (102, 202) of the housing (101, 201) arranged below the vacuum chamber (105, 205), and
the at least one source being mountable at an upper side of the vacuum chamber (105, 205).

2. The apparatus according to claim 1, wherein the front side of the vacuum chamber (105, 205) has a flat surface having an opening formed therein, and the door (106, 206) is realized as a plate, held externally at an edge of the opening, with which the opening is sealable in vacuum-tight fashion.

3. The apparatus according to claim 2, wherein the vacuum chamber (105, 205) has a cuboidal basic shape, one side of the cube forming the front side.

4. The apparatus according to claim 1, wherein at least one sample is receivable on the sample holder (120) in a sample receptacle reversibly fastenable on the sample holder.

5. The apparatus according to claim 1, wherein each of the at least one sources is received in a removable feedthrough and is configured to be fastened thereto on the upper side of the vacuum chamber (105, 205).

6. The apparatus according to claim 5, wherein there is arranged above the at least one source a protective hood (111, 211) which comprises a switch element that activates upon opening of the protective hood (111, 211) and is connected to an interruptor for the power supply of the at least one source.

7. The apparatus according to claim 1, wherein the housing (101, 201) abuts laterally against the vacuum chamber (105, 205) at a maximum lateral extension of the vacuum chamber (105, 205).

8. The apparatus according to claim 1, wherein the electronic control system is arranged below and/or behind the vacuum chamber (105, 205).

9. The apparatus according to claim 1, characterized by flanges located laterally on the vacuum chamber (205), onto which attachments fed through the housing can be attached.

10. The apparatus according to claim 1, wherein the vacuum chamber (105, 205) comprises at least one connector (114, 124) for connecting a vacuum supply to the vacuum chamber, wherein the at least one connector is arranged exclusively on a back side (113) of the vacuum chamber (105, 205).

11. The apparatus according to claim 1, wherein a device for carrying out sample cryopreparation is arranged inside the vacuum chamber (105, 205).

12. The apparatus according to claim 1, wherein a quartz oscillator for measuring the deposited coating material layer thickness is arranged in the vacuum chamber (105, 205).
